(19) United States
(12) Patent Application Publication
(10) Pub. No.: US 2007/0165257 A1
(43) Pub. Date: Jul. 19, 2007

(54) Image processing method, image processing apparatus, image forming apparatus and recording medium

(75) Inventor: Takeshi Owaku, Yamatokoriyama-shi (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 11/655,612

(22) Filed: Jan. 18, 2007

(30) Foreign Application Priority Data
Jan. 18, 2006 (JP) 2006-010321

(51) Int. Cl. G03F 3/08; G06F 15/00

(52) U.S. Cl. 358/1.9; 358/518; 358/461

(57) ABSTRACT

An image processing apparatus comprising reading means for reading document images; extracting means for extracting the characteristic amounts representing the characteristics of color information from first and second image data read from the images of first and second documents respectively; calculating means for calculating the difference between the two extracted characteristic amounts; determining means for determining the magnitude relationship between the calculated difference and a predetermined value; judging means for judging, on the basis of the result of the magnitude judgment, whether processing should be carried out for the second image data; and means for processing the second image data when it is judged that the processing should be carried out.

### CROSS-REFERENCE TO RELATED APPLICATIONS

This Nonprovisional application claims priority under 35 U.S.C. §119(a) on Patent Application No.2006-10321 filed in Japan on Jan. 18. 2006, the entire contents of which are hereby incorporated by reference.

### BACKGROUND OF THE INVENTION

1. Field of the Invention

The present invention relates to an image processing method, an image processing apparatus, an image forming apparatus, and a recording medium, capable of carrying out processing without causing change in hue even when generation copying is repeated.

2. Description of Related Art

Conventionally, image forming apparatuses based on the electrophotographic process or inkjet technology, such as copiers and printers, were produced. With the advance of the digital image processing technology, apparatuses capable of reproducing color images having high quality, such as full color digital copiers and multifunctional apparatuses, have been made available commercially.

As documents, image information of which is copied using such an image forming apparatus, in addition to general printed documents, documents, image information of which was output from the above-mentioned conventional image forming apparatuses based on the electrophotographic process or inkjet technology, are used occasionally so as to be copied again. This type of copying is referred to as generation copying. When such a document is copied, a problem of change in hue occurs between the image of the original document and the image of the copied document, although this problem is not significant when a general printed document is copied.

For the purpose of solving this kind of problem, a method is disclosed in which multiple parameters, such as a parameter for minimizing the copy color difference between the original document and a first-generation copy, and a parameter for minimizing the copy color difference between the original document and a second-generation copy, are obtained beforehand and stored in a storage device, the optimum parameter is selected manually by the user at the time of copying, and a copy corrected in hue is output (see Japanese Patent No. 3009442, for example).

However, in the technology described in Japanese Patent No. 3009442, the user is required to know which generation the document to be copied is, and the user is required to switch parameter setting at each copying. However, it is sometimes unknown whether the document to be copied is a document output as a generation copy or not, and it is practically difficult to know which generation the document to be copied is. Hence, when generation copying is carried out, there is a problem of possible danger that appropriate processing cannot be performed.

### BRIEF SUMMARY OF THE INVENTION

In consideration of these circumstances, the present invention is intended to provide an image processing method, an image processing apparatus, an image forming apparatus, and a recording medium, capable of carrying out color correction only when there may be a change in hue, without requiring the user to know which generation the document to be copied is, by extracting the characteristics of color information from first and second image data read from the images of first and second documents respectively and by judging, on the basis of the difference therebetween, whether processing for the second image data is carried out or not.

The image processing method according to the present invention, for processing image data read from documents, comprises the step of extracting the characteristics of color information from first and second image data read from the images of first and second documents respectively; calculating the difference between the two extracted characteristics; determining the magnitude relationship between the calculated difference and a predetermined value; judging whether or not processing should be carried out for said second image data, based on determination; and carrying out the processing for said second image data when it is judged that the processing should be carried out.

In the present invention, the characteristics of color information are extracted from first and second image data read from the images of first and second documents respectively, and a judgment is made, on the basis of the difference therebetween, as to whether processing for the second image data is carried out or not. When there is a difference in hue between the original document and its output copy, the difference increases gradually as generation copying is repeated, and the hue of the output copy becomes significantly different from that of the original document. In the present invention, color correction is carried out using the color information of the original document as an indicator at the time when image formation is performed by copying. As a result, image data having a hue close to that of the original document can be obtained.

The image processing apparatus according to the present invention, for processing image data read from document images, comprises a reading section for reading documents; an extracting section for extracting the characteristics of color information from first and second image data read from the images of first and second documents respectively using said reading section; a calculating section for calculating the difference between the two extracted characteristics; a determining section for determining the magnitude relationship between the calculated difference and a predetermined value; a judging section for judging whether or not processing should be carried out for said second image data, based on the determination; and a carry out section for carrying out the processing for said second image data when it is judged that the processing should be carried out.

In the present invention, the characteristics of color information are extracted from first and second image data read from the images of first and second documents respectively, and a judgment is made, on the basis of the difference therebetween, as to whether processing for the second image data is carried out or not. When there is a difference in hue between the original document and its output copy, the difference increases gradually as generation copying is repeated, and the hue of the output copy becomes significantly different from that of the original document. In the present invention, color correction is carried out using the color information of the original document as an indicator at the time when image formation is performed by copying. As a result, image data having a hue close to that of the original document can be obtained.

The image processing apparatus according to the present invention is characterized in that the characteristics extracted using said extracting section are the average values of the pixels values for respective color components formed of multiple pixels constituting the image data.

In the present invention, since the average values of the pixel values for the respective color components are used as the characteristics extracted using the extracting section, judgment accuracy is improved without increasing the size of the circuit.

The image processing apparatus according to the present invention further comprises an adding section for adding the information on the characteristics extracted from said first image data to said first image data.

In the present invention, since the information on the characteristics extracted from the first image data is added to the first image data, the information on the average values of the pixel values for respective CMY colors, for example, is added to output image data.

The image processing apparatus according to the present invention comprises an extracting section for extracting the characteristics of said first image data from the additional information; and a calculating section for calculating the average values of the pixel values for respective color components formed of multiple pixels constituting said second image data.

In the present invention, the additional information is extracted from the first image data, and the average values of the pixel values for the respective color components are calculated as the characteristics of the second image data. For this reason, it is not always necessary to read the first document and the second document simultaneously, and a judgment as to whether there is a change in hue or not is made by reading only the second document.

The image processing apparatus according to the present invention comprises a calculating section for calculating correction values to be added to the pixel values of the pixels constituting said second image data so that the difference between the two extracted characteristics becomes minimum when said difference is judged to be larger than the predetermined value; and an adding section for adding the calculated correction values to said pixel values.

In the present invention, since correction is carried out so that the difference between the two characteristics extracted using the extracting section becomes minimum when the calculated difference is judged to be larger than the predetermined value, the processed second image data has a hue close to that of the first image data.

The image forming apparatus according to the present invention comprises the image processing apparatus according to any one of the above-mentioned aspects of the present invention, and an image forming section for forming an image on a sheet on the basis of the second image data processed using the image processing apparatus.

In the present invention, since an image is formed on a sheet on the basis of the second image data processed using the image processing apparatus, a copy having a hue close to that of the original document is output.

The recording medium according to the present invention stores thereon a computer program capable of carrying out the step of controlling the extraction of the characteristics of color information from respective first and second image data having been input; the step of controlling the calculation of the difference between the two extracted characteristics; the step of controlling the judgment of the magnitude relationship between the calculated difference and a predetermined value; and the step of controlling the judgment, on the basis of the result of the magnitude judgment, as to whether processing should be carried out for the second image data.

In the present invention, a computer controls the extraction of the characteristics of color information from first and second image data and controls the judgment, on the basis of the difference therebetween, as to whether the processing for the second image data is carried out or not. Hence, color correction using the color information of the original document can be carried out by computer processing.

In the present invention, the characteristics of color information are extracted from first and second image data read from the images of first and second documents respectively, and a judgment is made, on the basis of the difference therebetween, as to whether processing for the second image data is carried out or not. When there is a difference in hue between the original document and its output copy, the difference increases gradually as generation copying is repeated, and the hue of the output copy becomes significantly different from that of the original document. In the present invention, color correction is carried out using the color information of the original document as an indicator at the time when image formation is performed by copying. As a result, image data having a hue close to that of the original document can be obtained.

In the present invention, the average values of the pixel values for respective color components are used as the characteristics extracted using the extracting section. Hence, judgment accuracy can be improved without increasing the size of the circuit.

In the present invention, the information on the characteristics extracted from the first image data is added to the first image data. For example, a bit sequence pattern being equivalent to the information on the average values of the pixel values for the respective CMY colors is added to the output image data, and this pattern is extracted at the time of generation copying. With this configuration, it is possible to judge whether hue correction is necessary or not.

In the present invention, the additional information is extracted from the first image data, and the average values of the pixel values for the respective color components are calculated as the characteristics of the second image data. For this reason, it is not always necessary to read the first document and the second document simultaneously, and a judgment as to whether there is a change in hue or not can be made by reading only the second document.

In the present invention, correction is carried out so that the difference between the two characteristics extracted using the extracting section becomes minimum when the calculated difference is judged to be larger than the predetermined value. Hence, the hue of the processed second image data becomes close to that of the first image data. The hue of generation copying can thus be improved.

In the present invention, since an image is formed on a sheet on the basis of the second image data processed using the image processing apparatus, a copy having a hue close to that of the original document can be output.

The above and further objects and features of the invention will more fully be apparent from the following detailed description with accompanying drawings.

### BRIEF DESCRIPTION OF THE SEVERAL VIEWS OF THE DRAWINGS

FIG. 1 is a block diagram illustrating the overall configuration of a digital multifunctional apparatus according to an embodiment of the present invention;

FIG. 2 is a block diagram illustrating the inner configuration of the image processing section of the apparatus;

FIG. 3 is a block diagram illustrating the details of the color component conversion section of the apparatus;

FIG. 4 is an explanatory view illustrating a block extraction method according to the embodiment;

FIG. 5 is a schematic view showing an example of a row of blocks generated using the additional information generation section of the apparatus;

FIG. 6 is a block diagram illustrating the inner configuration of an image processing apparatus in which a computer program recorded on a recording medium according to the present invention is installed; and

FIG. 7 is a flowchart illustrating the procedure of processing carried out by the image processing apparatus.

### DETAILED DESCRIPTION OF THE INVENTION

The present invention will be described below specifically referring to the drawings showing embodiments thereof

### Embodiment 1

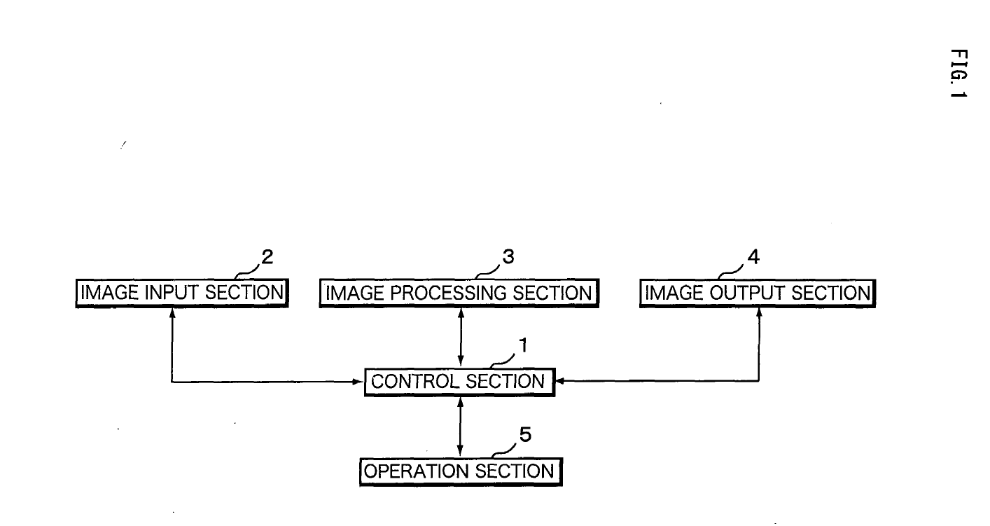

FIG. 1 is a block diagram illustrating the overall configuration of a digital multifunctional apparatus according to this embodiment. This multifunctional apparatus comprises a control section 1, an image input section 2, an image processing section 3, an image output section 4, and an operation section 5. The control section 1 comprises a CPU for controlling these hardware sections, a ROM in which a control program is stored, and a RAM for temporarily storing data and the like obtained during control. The control section 1 loads the control program stored in the ROM into the RAM at the time of power on, and executes the loaded control program so that the apparatus operates wholly as an image forming apparatus according to the present invention.

The image input section 2 is means for optically reading a document image from a document and comprises a light source for applying light to the document to be read, and an image sensor, such as a CCD (charge-coupled device). The image input section 2 focuses an image of the light reflected from the document placed at a predetermined reading position on the image sensor, and outputs RGB (R: red, G: green, and B: blue) analog electrical signals. The analog electrical signals output from the image input section 2 are input to the image processing section 3.

The image processing section 3 converts the analog electrical signals output from the image input section 2 into digital signals, carries out various color adjustment processing depending on the image, and generates image signals to be output. The generated image signals are output to the image output section 4 provided at the subsequent stage. In this embodiment, CMYK (C: cyan, M: magenta, Y: yellow, and K: black) signals are generated as the image signals to be output. Furthermore, when there is a danger that the hue of a copy changes in comparison with that of the original document at the time of generation copying, the image signals (image data) are corrected, and image signals representing a hue close to that of the original document are output.

The image output section 4 is means for forming an image on a sheet, such as paper or OHP film, on the basis of the image signals output from the image processing section 3. Hence, the image output section 4 comprises a charger for charging a photoreceptor to a predetermined potential, a laser scanning unit for forming electrostatic latent images on the surface of the photoconductive drum by generating laser light depending on the image data, a developing unit for making the electrostatic latent images formed on the surface of the photoconductive drum visible by supplying toner thereto, and a transfer unit (not shown) for transferring the toner images formed on the surface of the photoconductive drum to sheets. The image output section 4 thus forms images desired by the user on sheets through the electrophotographic system. Instead of the electrophotographic system that uses a laser writer for image formation, a ink jet system, a thermal transfer printing system, or a sublimation dye transfer printing system may also be employed to form images. The operation section 5 has various keys for receiving operation instructions from the user.

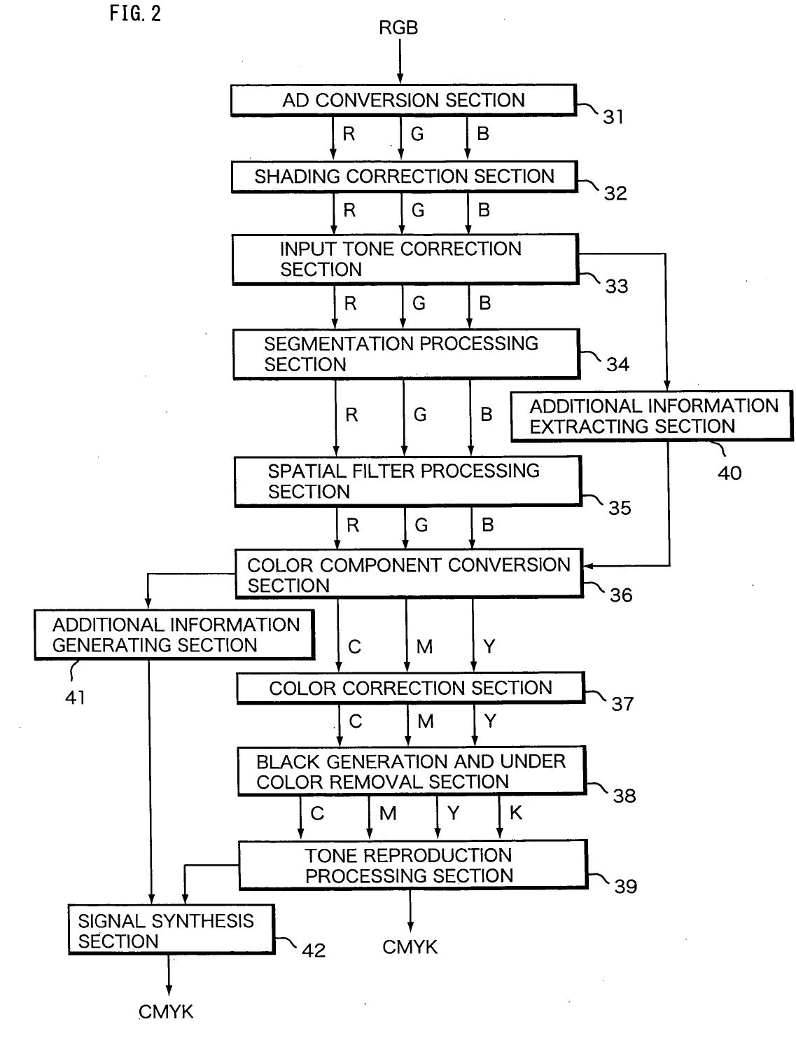

FIG. 2 is a block diagram illustrating the inner configuration of the image processing section 3. The image processing section 3 comprises an AD conversion section 31, a shading correction section 32, an input tone correction section 33, a segmentation processing section 34, a spatial filter processing section 35, a color component conversion section 36, a color correction section 37, a black generation and under color removal section 38, a tone reproduction processing section 39, an additional information extraction section 40, an additional information generation section 41, and a signal synthesis section 42.

The AD conversion section 31 converts the analog RGB signals input from the image input section 2 into the digital RGB signals. The shading correction section 32 carries out processing to eliminate various distortions caused in the illumination system, the image focusing system, and the imaging sensing system for the digital RGB signals output from the AD conversion section 31. In this embodiment, the RGB signals obtained after the AD conversion and the shading correction may be captured from the outside. In this case, the AD conversion section 31 and the shading correction section 32 are not required to be incorporated.

The input tone correction section 33 adjusts the color balance of RGB reflectivity signals and, at the same time, converts the signals into signals that can be easily handled by the image processing system, such as density signals.

The segmentation processing section 34 generates an area signal for each pixel or each block to improve the reproducibility of texts, particularly black texts (achromatic texts) or colored texts (chromatic texts), in documents including texts and photographic images, and to improve tone in the areas of printed-picture images which is comprised halftone, photographic-picture which is comprised continuous tone (for example, silver halide photography).

The spatial filter processing section 35 carries out low-pass filter processing for the areas determined to be printed-picture using the segmentation processing section 34 to eliminate input halftone components, and carries out slight enhancement processing or smoothing processing for the areas determined to be photographs on photosensitive paper sheets depending on the system.

The color component conversion section 36 converts the RGB signals into the CMY signals with complementary color transformation, calculates correction values using color information embedded in input image data and using color information obtained from the input image data, and corrects the CMY signals. The processing will be described later in detail.

The color correction section 37 carries out processing for eliminating color impurity due to spectral characteristics of the CMY color materials containing useless absorption component and also carries out processing for color matching between an original document and its copy to attain faithful color reproduction.

The black generation and under color removal section 38 increases the amount of black generation and under color removal in an image area extracted as a black text using the segmentation processing section 34, and determines the amount of under color removal accordingly. Furthermore, the black generation and under color removal section 38 appropriately adjusts the amount of black generation and under color removal in image areas extracted as areas of printed-picture or areas of photographic-picture on photosensitive paper sheets depending on the image processing system, thereby converting the three CMY color signals into four color (CMYK) signals.

The gradation reproduction section 39 carries out optimal binary or multi-level dithering processing on the basis of the segmentation class information using such as error diffusion processing or dithering processing. The signals obtained using these processing are output to the image output section 4 disposed in the subsequent stage.

The added information extraction section 40, the added information generation section 41, and the signal synthesis section 42 will be described later in detail.

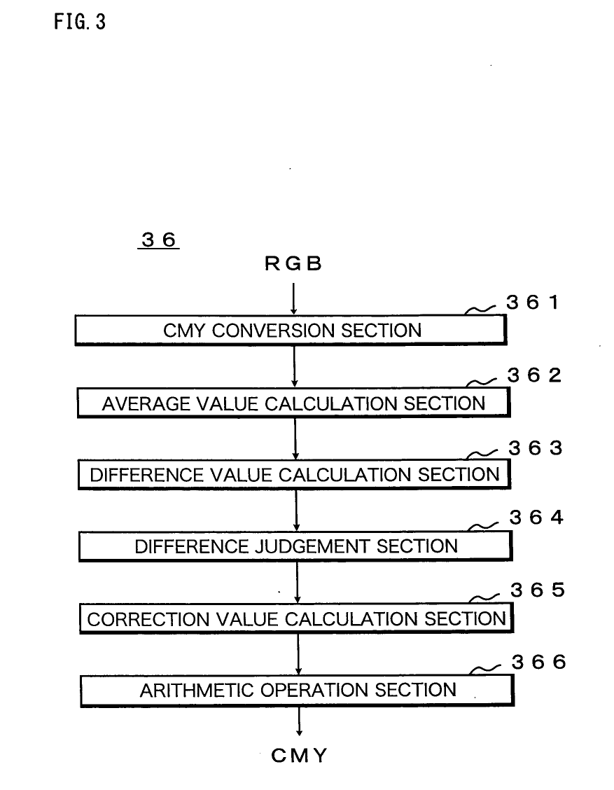

FIG. 3 is a block diagram illustrating the details of the color component conversion section 36. The color component conversion section 36 comprises a CMY conversion section 361, an average value calculation section 362, a difference value calculation section 363, a difference judgment section 364, a correction value calculation section 365, and an arithmetic operation section 366.

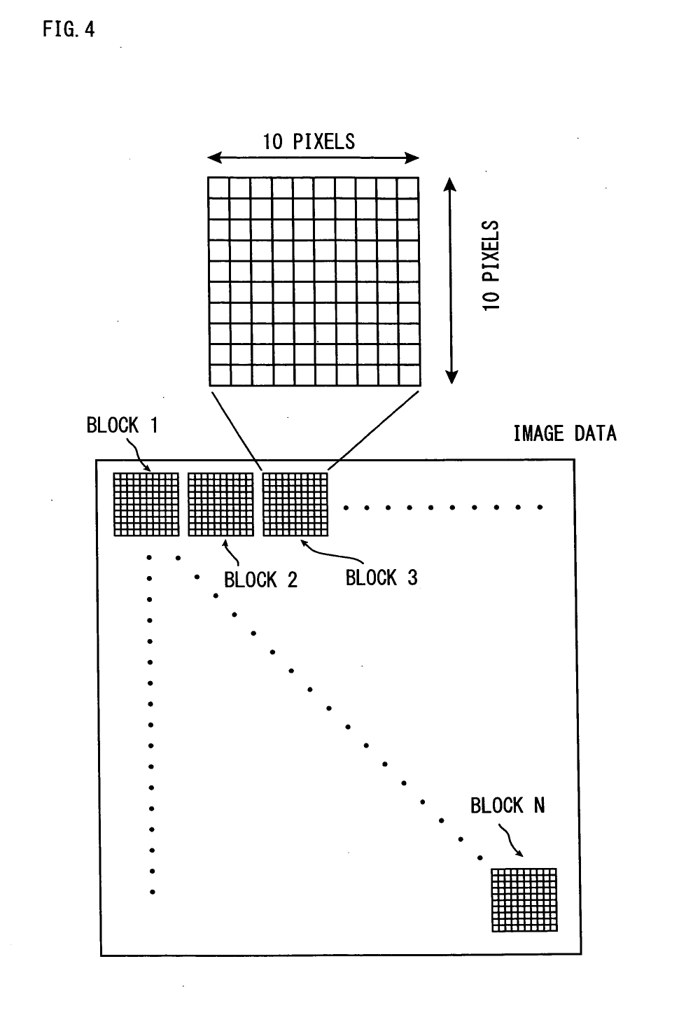

The CMY conversion section 361 converts the RGB signals having subjected up to the space filter processing into the CMY signals that are made complementary to the RGB signals. The average value calculation section 362 obtains the average values of the pixel values for the respective CMY colors in block units. FIG. 4 is an explanatory view illustrating a block extraction method. This explanatory view shows how N blocks are extracted from image data formed of multiple pixels, and respective pixels have CMY values (pixel values). Each block has a small area of 10×10 pixels, for example. For the block extraction, image data may be subjected to sampling at equal intervals, or may be subjected to sampling at equal intervals while overlapped slightly at the boundary of each interval. The average value calculation section 362 obtains the average values of the pixel values for the respective CMY colors in each block, the image data of which was subjected to sampling. In other words, the sum of the pixel values for each of the CMY colors in each block is calculated and divided by the number of pixels in the block to obtain the average value. The average value calculation section 362 averages the average values calculated for each block and calculates the average values for the entire image.

The difference value calculation section 363 obtains the difference between the average value of the pixel values for each color component of the entire image, obtained using the average value calculation section 362, and the average value of the pixel values for each color component of the original document, extracted from the input image data. The difference judgment section 364 compares the difference value calculated for each color component with the corresponding preset threshold value Thc, Thm, or Thy, and judges whether it is necessary to correct the CMY signals. In other words, when the difference value for one of the color components is larger than the corresponding threshold value, there is a danger that change in hue may occur at the time of copying. In this case, the difference judgment section 364 judges that correction is necessary.

When the difference judgment section 364 judges that correction is necessary, the correction value calculation section 365 obtains correction values that are used to correct the pixel values for the respective CMY colors. The arithmetic operation section 366 corrects the CMY signals using the correction values to obtain CMY signals that are corrected in hue.

The correction value calculation method using the correction value calculation section 365 will be described below.

The correction value calculation section 365 uses the average values calculated from original image data as ideal values, and obtains correction values so that the corrected pixel values for the respective CMY colors become close to the ideal values. When the pixel values for the respective CMY colors before correction are C₀, M₀, and Y₀, when the pixel values for the respective CMY colors after correction are C₁, M₁, and Y₁, and when the correction values are a, b, and c, the relationship among the pixel values for the respective CMY colors before and after correction can be represented as described below.

$$\begin{matrix}{C}_{1} = {C}_{0} + a \\ {M}_{1} = {M}_{0} + b \\ {Y}_{1} = {Y}_{0} + c\end{matrix} \} \qquad ( 1 )$$

Hence, When the average values in a block unit, calculated from the image data to be corrected, are C₀⁽ⁱ⁾, M₀⁽ⁱ⁾, and Y₀⁽ⁱ⁾, when the average values in the block unit after correction are C₁⁽ⁱ⁾, M₁⁽ⁱ⁾, and Y₁⁽ⁱ⁾, and when the average values in the block unit, calculated from original image data, are C_{org}⁽ⁱ⁾, M_{org}⁽ⁱ⁾, and Y_{org}⁽ⁱ⁾ (wherein i=1, 2, . . . , N), the square sum E of the color difference between the data after correction and the data of the original document is represented by the following expression.

E=(C₁⁽¹⁾−C_{org}⁽¹⁾)²+(M₁⁽¹⁾−M_{org}⁽¹⁾)²+(Y₁⁽¹⁾−Y_{org}⁽¹⁾)²+ . . . (C₁^{(N)}−C_{org}^{(N)})²+(M₁^{(N)}−M_{org}^{(N)})²+(Y₁^{(N)}−Y_{org}^{(N)})² (2)

Since each of the pixel values for the respective CMY colors before correction and each of the pixel values for the respective CMY colors after correction have the relationship represented by Expression 1, Expression 2 can be rewritten as described below.

E=(C₀⁽¹⁾+a−C_{org}⁽¹⁾)²+(M₀⁽¹⁾+b−M_{org}⁽¹⁾)²+(Y₀⁽¹⁾+c−Y_{org}⁽¹⁾)²+ . . . (C₀^{(N)}+a−C_{org}^{(N)})²+(M₀^{(N)}+b−M_{org}^{(N)})²+(Y₀^{(N)}+c−Y_{org}^{(N)})² (3)

Hence, the correction values a, b, and c can be obtained using the least squares method wherein a, b, and c are used as variables. The arithmetic operation section 366 adds the calculated correction values to the pixel values of the respective pixels to obtain corrected image data.

In this embodiment, the difference value calculation section 363, the difference judgment section 364, the correction value calculation section 365, and the arithmetic operation section 366 are each configured as an independent component. However, they may be configured as one hardware device.

When an object to be processed is a generation copy, and when there is a danger that the hue of the copy may be changed by copying, the color component conversion section 36 calculates the correction values and carries out hue correction as described above. However, when an object to be processed is image data read from an original document, the average values of the pixel values for the respective CMY colors, calculated similarly as described above, are embedded in the image data. The average value information to be embedded in the image data is hereafter referred to as additional information.

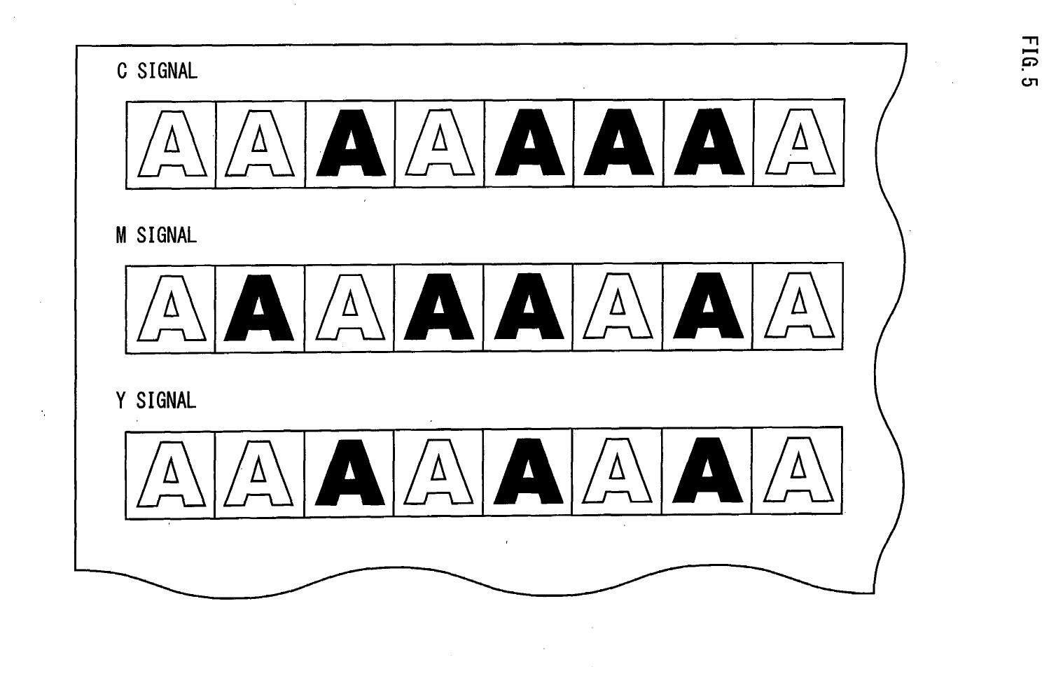

The additional information is embedded using the additional information generation section 41 and the signal synthesis section 42 of the image processing section 3. More specifically, when the copy of an original document is output, the additional information is added by embedding a row of blocks having a color (e.g., yellow) that is difficult to be perceived by human eyes. FIG. 5 is a schematic view showing an example of a row of blocks generated using the additional information generation section 41. For example, the average values of the pixel values for the respective CMY colors in an entire image, calculated using the average calculation section 362, are represented by bits. As shown in FIG. 5, a row of blocks, each block containing some pixels (e.g., 10×10 pixels), is taken as an example and generated while a block with no code is represented by “0” and a block with a code is represented by “1.” In the example shown in FIG. 5, text “A” is used as a code. Outlined white text “A” represents a state having no code, and solid-black text “A” represents a state having a code. The row of blocks generated is output to the signal synthesis section 42 and synthesized with the image signal output from the gradation reproduction section 39.

For example, when an average value calculated using the average calculation section 362 is represented by 8 bits, a row of 8 blocks is generated, and additional information can be embedded. In the example shown in FIG. 5, “00101110” (=46) is embedded as the average value of the pixel values for the C signal. Furthermore, the average values of the pixel values for the M and Y signals are embedded in other respective rows.

The average value of the pixel values for each of the C, M, and Y signals may be embedded in multiple places instead of only one place. Furthermore, the average value of the pixel values for each of the C, M, and Y signals may be embedded repeatedly on the right side of FIG. 5. Still further, the average value of the pixel values for the M signal may be embedded next to the average value of the pixel values for the C signal, and the average value of the pixel values for the Y signal may be embedded right next to the average value of the pixel values for the M signal. In other words, the average values of the pixel values for the C, M, and Y signals may be embedded repeatedly in this order.

In addition, instead of the average values of the pixel values for the respective color components of an original document, the identification information of the document may be embedded as information to be embedded in image data, and the information on the average values of the pixel values for the respective color components of the original document may be brought into correspondence with the above-mentioned identification information of the document and stored in a storage device, such as a hard disk drive.

The additional information added using the additional information generation section 41 and the signal synthesis section 42 are extracted using the additional information extraction section 40 when generation copying is carried out. In other words, since the information on the average values of the pixel values for the respective CMY colors is embedded using the above-mentioned method when an original document is copied by the digital multifunctional apparatus according to this embodiment, when generation copying is carried out, rows of blocks are detected from image data, whereby embedded information can be obtained.

### Embodiment 2

A configuration wherein hardware devices are used to attain various processing is described in Embodiment 1. However, it may also be possible to attain the image processing apparatus according to the present invention using software processing.

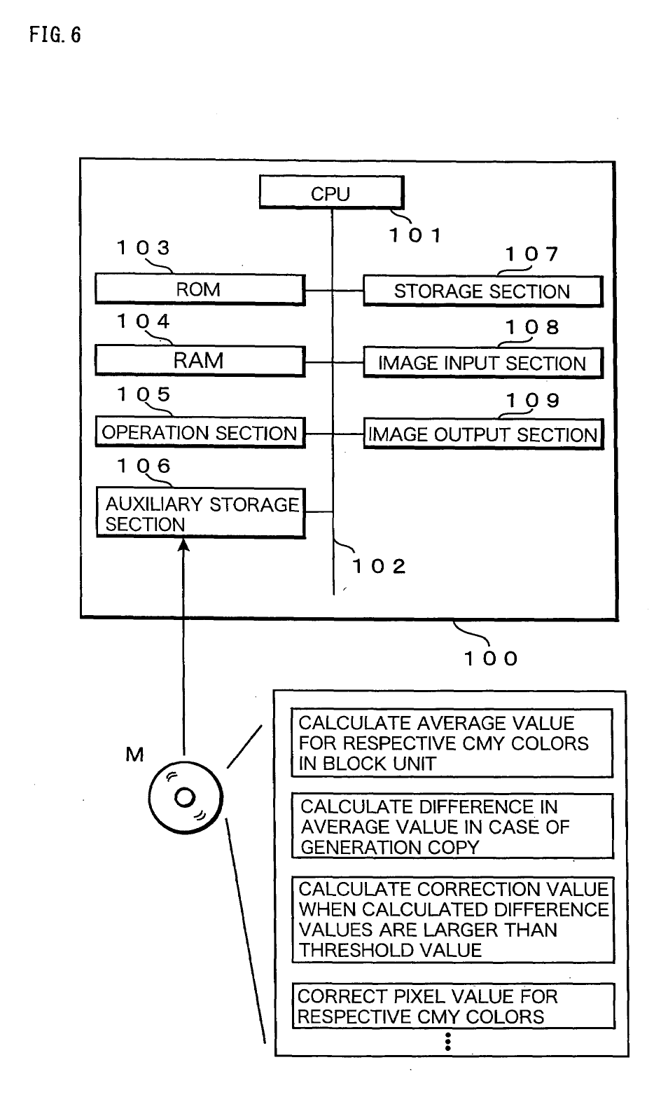

FIG. 6 is a block diagram illustrating the inner configuration of an image processing apparatus in which a computer program recorded on a recording medium according to the present invention is installed. Numeral 100 in the figure designates the image processing apparatus according to this embodiment, more specifically, a personal computer or a work station. The image processing apparatus 100 has a CPU 101. This CPU 101 loads a control program stored beforehand in a ROM 103 connected to a bus 102 into a RAM 104 and executes the control program, thereby controlling hardware devices, such as an operation section 105, an auxiliary storage section 106, a storage section 107, an image input section 108, and an image output section 109.

The operation section 105 has a keyboard, a mouse, etc. to select image data to be processed, to input parameters required for image processing, and to receive image processing start instructions and the like. The auxiliary storage section 106 has a reading device for reading computer programs from a recording medium M on which the computer program according to the present invention is recorded. As the recording medium M, an FD (flexible disk), a CD-ROM, or the like can be used. The storage section 107 has a hard disk drive or the like having magnetic recording media and stores the computer program read using the auxiliary storage section 106 and image data input via the image input section 108.

The image input section 108 is an interface for connection to a scanner, a digital camera, etc. The image output section 109 is an interface for connection to a printer or the like.

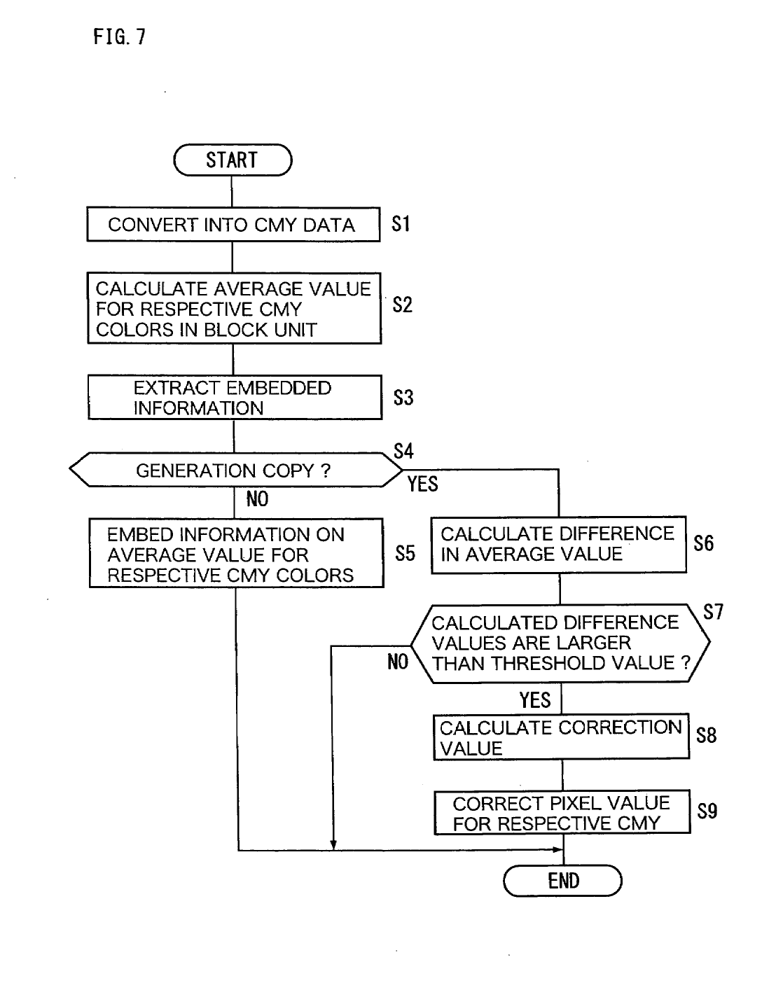

FIG. 7 is a flowchart illustrating the procedure of processing that is carried out by the image processing apparatus 100. The CPU 101 of the image processing apparatus 100 converts image data captured via the image input section 108 into CMY data (at step S1), and calculates the average values of the pixel values for the respective CMY colors in block units (at step S2). When the captured image data is CMY data, the processing at step S1 can be omitted.

Next, the CPU 101 extracts information embedded in the captured image data (at step S3), and judges, on the basis of the extracted information, whether a document to be copied is a generation copy or not (at step S4). When the document to be copied is an original document, the information (additional information) on the average values of the pixel values for the respective color components is supposed to be embedded. Hence, when the information is not extracted, the CPU 101 judges that the document to be copied is not a generation copy (NO at step S4), and embeds the information on the average values of the pixel values for the respective CMY colors, calculated at step S2, in the captured image data (at step S5). After the embedding of the information on the average values is completed, the processing according to this flowchart ends.

On the other hand, when the information on the average values of the pixel values for the respective CMY colors is embedded in the captured image data, the CPU 101 judges that the document to be copied is a generation copy (YES at step S4), and then the CPU 101 calculates the difference in the average values of the pixel values for each of the CMY colors in block units on the basis of the information on the average values of the pixel values for the respective CMY colors, calculated at step S2, and the information on the average values extracted at step S3 (at step S6).

Next, the CPU 101 judges whether the calculated difference values for the respective CMY colors are larger than the preset threshold values Thc, Thm, and Thy respectively (at step S7). When the CPU 101 judges that the calculated difference values are equal to or less than the respective threshold values Thc, Thm, and Thy (NO at step S7), the CPU 101 judges that correction is not required for the image data, and the processing according to the flowchart ends.

When the CPU 101 judges that one of the calculated difference values is larger than the corresponding threshold value Thc, Thm, or Thy (YES at step S7), the CPU 101 judges that there is a danger that the hue of the copy is changed from that of the original document, and calculates correction values for correcting the image data (at step S8). Each of the correction values can be obtained using the least squares method so that the square mean value of the difference between each of the average values of the pixel values for the respective CMY colors, extracted from the original document at step S3, and each of the pixel values of the respective CMY colors after correction becomes minimum. The CPU 101 corrects the pixel values for the respective CMY colors of the image data input on the basis of the calculated correction values (at step S9), and the processing according to the flowchart ends.

This embodiment is configured that the CPU 101 carries out various operations and judgments. However, the embodiment may also be configured that a special-purpose chip for carrying out operations relating to image processing is provided separately and that operations are performed according to instructions from the CPU 101.

Furthermore, as the recording medium M according to the present invention, in addition to the above-mentioned FD and CD-ROM, it is possible to use optical discs, such as MO, MD, and DVD discs; magnetic recording media, such as hard disk drives; card-like recording media, such IC cards, memory cards, and optical cards; and semiconductor memory devices, such as mask ROM, EPROM (erasable programmable read-only memory), EEPROM (electrically erasable programmable read-only memory), and flash ROM.

Still further, the computer program recorded on the recording medium M may be provided as a single application program or utility program, or the computer program may be built in another application program or utility program and provided as some functions of the program. For example, it is conceivable that, as a form of the computer program, the computer program is built in a printer driver and provided. In this case, image data generated using a given application program is subjected to color correction, translated into a printer language, and transmitted to a target printer.

Still further, this invention provides an embodiment for computer data signal which is imbedded in a carrier wave so as to practice of above mentioned computer program by transmitting electrically.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

What is claimed is:

1. An image processing method comprising the steps of:
extracting the characteristics of color information from first and second image data read from the images of first and second documents respectively;
calculating the difference between the two extracted characteristics;
determining the magnitude relationship between the calculated difference and a predetermined value;
judging whether or not processing should be carried out for said second image data, based on determination; and
carrying out the processing for said second image data when it is judged that the processing should be carried out.

2. An image processing apparatus comprising:
a reading section for reading documents; and
a controller capable of performing operations of:
extracting the characteristics of color information from first and second image data read from the images of first and second documents respectively using said reading section;
calculating the difference between the two extracted characteristics;
determining the magnitude relationship between the calculated difference and a predetermined value;
judging whether or not processing should be carried out for said second image data, based on the determination; and
carrying out the processing for said second image data when it is judged that the processing should be carried out.

3. The image processing apparatus according to claim 2, wherein the characteristics to be extracted are the average values of the pixels values for respective color components formed of multiple pixels constituting the image data.

4. The image processing apparatus according to claim 2, wherein said controller is further capable of adding the information on the characteristics extracted from said first image data to said first image data.

5. The image processing apparatus according to claim 4, wherein said controller is further capable of performing operations of:
extracting the characteristics of said first image data from the additional information; and
calculating the average values of the pixel values for respective color components formed of multiple pixels constituting said second image data.

6. The image processing apparatus according to claim 2, wherein said controller is further capable of performing operations of:
calculating correction values to be added to the pixel values of the pixels constituting said second image data so that the difference between the two extracted characteristics becomes minimum when said difference is judged to be larger than the predetermined value; and
adding the calculated correction values to said pixel values.

7. An image processing apparatus comprising:
a reading section for reading documents;
an extracting section for extracting the characteristics of color information from first and second image data read from the images of first and second documents respectively using said reading section;
a calculating section for calculating the difference between the two extracted characteristics;
a determining section for determining the magnitude relationship between the calculated difference and a predetermined value;
a judging section for judging whether or not processing should be carried out for said second image data, based on the determination; and
a carry out section for carrying out the processing for said second image data when it is judged that the processing should be carried out.

8. The image processing apparatus according to claim 7, wherein the characteristics extracted using said extracting section are the average values of the pixels values for respective color components formed of multiple pixels constituting the image data.

9. The image processing apparatus according to claim 7, further comprising an adding section for adding the information on the characteristics extracted from said first image data to said first image data.

10. The image processing apparatus according to claim 9, further comprising:
an extracting section for extracting the characteristics of said first image data from the additional information; and
a calculating section for calculating the average values of the pixel values for respective color components formed of multiple pixels constituting said second image data.

11. The image processing apparatus according to claim 7, further comprising:
a calculating section for calculating correction values to be added to the pixel values of the pixels constituting said second image data so that the difference between the two extracted characteristics becomes minimum when said difference is judged to be larger than the predetermined value; and
an adding section for adding the calculated correction values to said pixel values.

12. An image forming apparatus comprising:
said image processing apparatus according to claim 2; and
an image forming section for forming an image on a sheet on the basis of the second image data processed using said image processing apparatus.

13. An image forming apparatus comprising:
said image processing apparatus according to claim 7; and
an image forming section for forming an image on a sheet on the basis of the second image data processed using said image processing apparatus.

14. A recording medium storing thereon a computer program executable to perform the steps of:
controlling the extraction of the characteristics of color information from respective first and second image data having been input;
controlling the calculation of the difference between the two extracted characteristics;
controlling the judgment of the magnitude relationship between the calculated difference and a predetermined value;
controlling the judgment, on the basis of the result of the magnitude judgment, as to whether processing should be carried out for the second image data; and
controlling the execution of the processing for said second image data when it is judged that the processing should be carried out.
